(19) United States
(12) Patent Application Publication
(10) Pub. No.: US 2015/0325621 A1
(43) Pub. Date: Nov. 12, 2015

(54) LIGHT-EMITTING DIODE WITH A PLURALITY OF LIGHT-EMITTING ELEMENTS AND METHOD FOR MANUFACTURING SAME

(71) Applicant: Seoul Viosys Co., Ltd., Ansan-si (KR)

(72) Inventors: Ye Seul Kim, Ansan-si (KR); Kyoung Wan Kim, Ansan-si (KR); Yeo Jin Yoon, Ansan-si (KR)

(21) Appl. No.: 14/806,552

(22) Filed: Jul. 22, 2015

Related U.S. Application Data
(63) Continuation-in-part of application No. PCT/KR2013/001495, filed on Feb. 25, 2013.

(51) Int. Cl. H01L 27/15; H01L 33/00; H01L 33/62

(52) U.S. Cl. CPC H01L 27/15; H01L 33/62; H01L 33/005

(57) ABSTRACT

Disclosed are a light-emitting diode with a plurality of light-emitting elements and a method for manufacturing the same. The light-emitting diode includes: a plurality of light-emitting elements arranged on a substrate; a separation groove for separating adjacent light-emitting elements; an insulation material for filling at least a part of the separation; an electrical line for electrically connecting two adjacent light-emitting elements; and an insulation layer for insulating the electrical line from the side of the light-emitting elements. Each of the light-emitting elements includes a first conduction type semiconductor layer, an activation layer, and a second conduction type semiconductor layer, wherein the first conduction type semiconductor layer has an exposed upper surface obtained by removing the second conduction type semiconductor layer and the activation layer, the exposed upper surface being adjacent to the separation groove, and the electrical line being positioned upon the top of the insulation material. The separation groove is filled with the insulation material so as to prevent cutting of the electrical line and to increase the light-emitting area.

### PRIORITY CLAIMS AND CROSS-REFERENCE TO RELATED APPLICATION

This patent document is a continuation-in-part of, and claims priority and the benefits of, a Patent Cooperation Treaty (PCT) application number PCT/KR2013/001495, entitled “LIGHT-EMITTING DIODE WITH A PLURALITY OF LIGHT-EMITTING ELEMENTS AND METHOD FOR MANUFACTURING SAME” and filed with the Korean Intellectual Property Office (KIPO) on Feb. 25, 2013, the contents of which is incorporated by reference in their entirety.

### TECHNICAL FIELD

This patent document relates to a light emitting diode and a method for manufacturing the same. For example, the disclosed technology relates to a light emitting diode, which has a plurality of light emitting elements on a single substrate, and a method for manufacturing the same.

### BACKGROUND

An LED is a light emitting device having a lot of merits such as environmental friendliness, energy saving, long lifespan, and the like. However, since the LED is a direct current-driven device, the LED requires a converter in order to use AC power such as domestic AC power. The LED suffers from reduction in lifespan caused by shorter lifespan of the converter than that of the LED. In addition, the LED has a lot of problems such as 20% to 30% reduction in efficiency due to AC/DC conversion, deterioration in reliability due to use of the converter, environmental contamination, a large space for a product, design constraints, and the like.

### SUMMARY

Some implementations of the disclosed technology provides a light emitting diode including a plurality of light emitting elements, for example, a light emitting diode, which can prevent disconnection of a wiring and increase a light emitting area while ensuring electrical isolation between light emitting elements, and a method for manufacturing the same.

In one aspect, a light emitting diode is provided to include: a substrate; a plurality of light emitting elements arranged on the substrate; an isolation trench isolating adjacent light emitting elements from each other; an insulation material filling at least a portion of the isolation trench; a wiring electrically connecting two adjacent light emitting elements to each other; and an insulation layer insulating the wiring from a side surface of the light emitting elements, wherein each of the light emitting elements includes a first conductivity-type semiconductor layer, an active layer, and a second conductivity-type semiconductor layer, the first conductivity-type semiconductor layer has an upper surface exposed by removing the second conductivity-type semiconductor layer and the active layer; the exposed upper surface adjoining the isolation trench; the wiring is disposed over an upper side of the insulation material, and the insulation material has an upper surface which is flush with or disposed below the exposed upper surface of the first conductivity-type semiconductor layer.

Since the isolation trench is filled with the insulation material, there is no need to form the wiring in the isolation trench. Thus, since there is no need to form the isolation trench having a gently inclined sidewall, an entrance of the isolation trench can have a reduced width. Therefore, the light emitting diode can have a greater light emitting area than typical light emitting diodes.

In some implementations, the wiring can electrically connect the upper surface of the first conductivity-type semiconductor layer of a first light emitting element to the second conductivity-type semiconductor layer of a second light emitting element. In some implementations, a portion of a side surface of the second light emitting element is covered with the wiring and has a gentler slope than the sidewall of the isolation trench.

In some implementations, the isolation trench can be formed using dry or wet etching or using laser machining. In some implementations, the isolation trench can extend to an interior of the substrate. In some implementations, the isolation trench is formed by laser machining to have a decreasing width toward the substrate.

In some implementations, the insulation material can include a polyimide or nanoparticles.

In some implementations, the entrance of the isolation trench can have a width of 5 μm or less. In some implementations, the entrance of the isolation trench can have any width so long as the isolation trench can electrically isolate the light emitting elements. For example, the entrance of the isolation trench can have a width of 1 μm or more. In some implementations, the sidewall of the isolation trench can have a reverse slope. In some implementations, the insulation material includes nano-scale silica and a polyimide disposed over the silica.

In some implementations, a portion of the insulation layer can cover an upper surface of the insulation material.

In another aspect, a light emitting diode is provided to comprise: a substrate; a plurality of light emitting elements arranged on the substrate; an isolation trench isolating adjacent light emitting elements from each other; an insulation material filling at least a portion of the isolation trench; a wiring electrically connecting two adjacent light emitting elements to each other; and an insulation layer insulating the wiring from a side surface of the light emitting elements, wherein each of the light emitting elements includes a first conductivity-type semiconductor layer, an active layer and a second conductivity-type semiconductor layer, the first conductivity-type semiconductor layer has an upper surface exposed by removing the second conductivity-type semiconductor layer and the active layer, the exposed upper surface adjoining the isolation trench, the wiring is disposed over an upper side of the insulation material, and an air gap is disposed between the insulation material and the substrate.

In some implementations, the insulation material includes nano-scale silica and a polyimide disposed over the silica. In some implementations, a portion of the insulation layer covers an upper surface of the insulation material.

In another aspect, a method for manufacturing a light emitting diode includes: growing a first conductivity-type semiconductor layer, an active layer and a second conductivity-type semiconductor layer on a substrate; forming an etched recess exposing the first conductivity-type semiconductor layer by etching the second conductivity-type semiconductor layer and the active layer; forming an isolation trench to electrically isolate a plurality of light emitting elements from one another such that at least a portion of the isolation trench is formed in the etched recess; filling at least a portion of the isolation trench with an insulation material; forming an insulation layer covering a side surface of the plural light emitting elements; and forming a wiring electrically connecting adjacent light emitting elements, wherein a portion of the insulation layer covers the upper surface of the insulation material.

In some implementations, the insulation material has an upper surface which is flush with or disposed below the bottom surface of the etched recess. In some implementations, a sidewall of the etched recess has a gentler slope than a sidewall of the isolation trench. In some implementations, the forming of the isolation trench can include removing the first conductivity-type semiconductor layer by etching or laser machining. In some implementations, the forming of the isolation trench can further include performing sulfuric-phosphoric acid treatment after the first conductivity-type semiconductor layer is removed by etching or laser machining. In some implementations, the insulation material includes a polyimide or nano-scale silica.

In a light emitting diode according to some implementations of the disclosed technology, light emitting elements having a wiring formed thereon can be formed to have a reduced step height by filling an isolation trench with an insulation material. Thus, disconnection of the wiring can be prevented and an entrance of the isolation trench has a reduced width by forming the isolation trench having a sharply inclined sidewall. With this structure, the light emitting diode can prevent reduction in light emitting area due to formation of the isolation trench. Further, the light emitting diode has improved light extraction efficiency using the insulation material filling the isolation trench.

### BRIEF DESCRIPTION OF DRAWINGS

FIG. 1 is a sectional view of a typical light emitting diode.

FIG. 2 is a sectional view of an exemplary light emitting diode according to one embodiment of the disclosed technology.

FIG. 3 is a sectional view of an exemplary light emitting diode according to another embodiment of the disclosed technology.

FIGS. 4 to 11 are sectional views of light emitting diodes according to various embodiments of the disclosed technology.

FIGS. 12 to 16 are sectional views for explaining a method for manufacturing a light emitting diode according to embodiments of the present invention.

### DETAILED DESCRIPTION

While LED is used in various areas, several problems of the LED such as reduction in life span, reduction in efficiency, deterioration in reliability, etc., have been observed. To solve these problems, an LED which can be driven without a typical converter is being developed. Such an LED generally includes a plurality of light emitting elements on a substrate, and various circuits can be configured by electrically connecting the light emitting elements via interconnection lines.

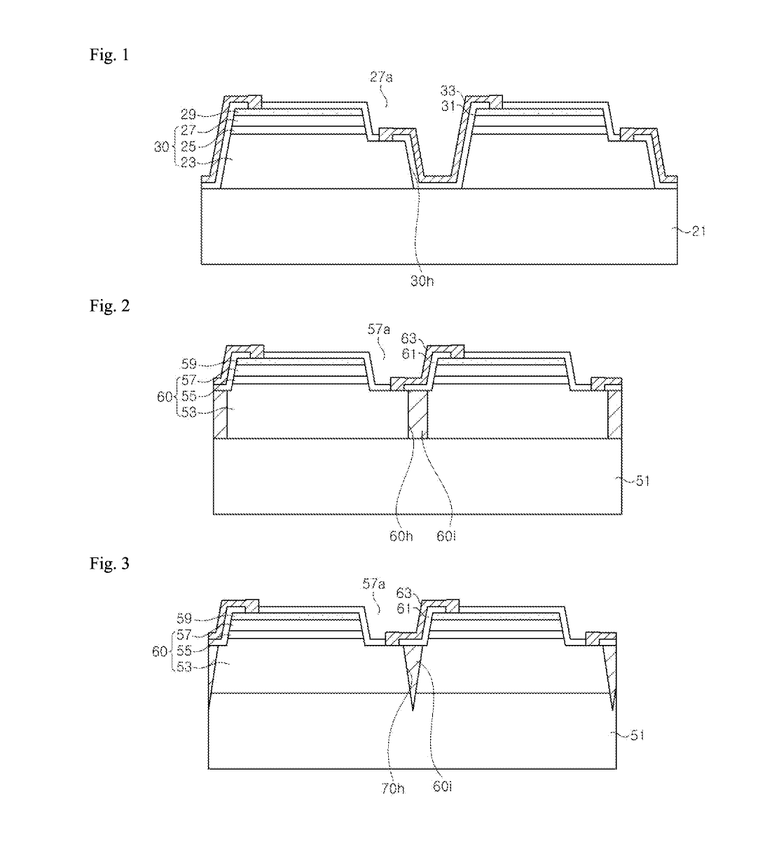

FIG. 1 is a schematic sectional view of a typical light emitting diode having a plurality of light emitting elements.

Referring to FIG. 1, the light emitting diode includes a substrate 21, a plurality of light emitting elements 30, a transparent electrode 29, an insulation layer 31, and a wiring 33, wherein the light emitting elements 30 include an n-type semiconductor layer 23, an active layer 25, and a p-type semiconductor layer 27.

The plural light emitting elements 30 are electrically isolated from each other by isolation trenches 30h on the substrate 21. In addition, an upper surface of the n-type semiconductor layer 23 is exposed through an etched recess 27a formed by removing the p-type semiconductor layer 27 and the active layer 25.

The wiring 33 electrically connects the n-type semiconductor layer 23 of one (first) light emitting element 30 to the p-type semiconductor layer 27 of another (second) light emitting element 30. The wiring 33 can connect the exposed upper surface of the n-type semiconductor layer 23 to the transparent electrode 29, as shown in FIG. 1. The insulation layer 31 is disposed between the wiring 33 and the light emitting elements 30 and insulates the wiring 33 from a side surface of the light emitting elements 30.

Typically, the light emitting diode includes the plural light emitting elements 30, which are connected in series by the wiring 33, and can be driven by high-voltage alternating-current power.

In the typical light emitting diode, the isolation trench 30h reaching an upper surface of the substrate 21 is formed in order to ensure electrical isolation between the light emitting elements 30. A portion of the wiring 33 is formed on the side surface of the light emitting elements 30 in the isolation trench 30h. The light emitting elements 30 generally have a height of about 5 μm or more, and thus, when the side surface of the light emitting elements 30 is sharply inclined, it is difficult to form the wiring 33 on the side surface of the light emitting elements 30, and the wiring 33 is likely to suffer from disconnection. To prevent disconnection of the wiring 33, the side surface of the light emitting elements 30 is generally formed to have a gentle slope.

However, when the side surface of the light emitting elements 30 has a gentle slope, an entrance of the isolation trench 30h generally has a relatively wide width of about 30 μm for electrical isolation between the light emitting elements 30, thereby reducing a light emitting area.

Hereinafter, various implementations of the disclosed technology will be described in detail with reference to the accompanying drawings. It should be understood that the disclosed technology is not limited to the following embodiments and can be embodied in different ways. In the drawings, the widths, lengths, thicknesses and the like of components can be exaggerated for convenience. Like components will be denoted by like reference numerals throughout the specification.

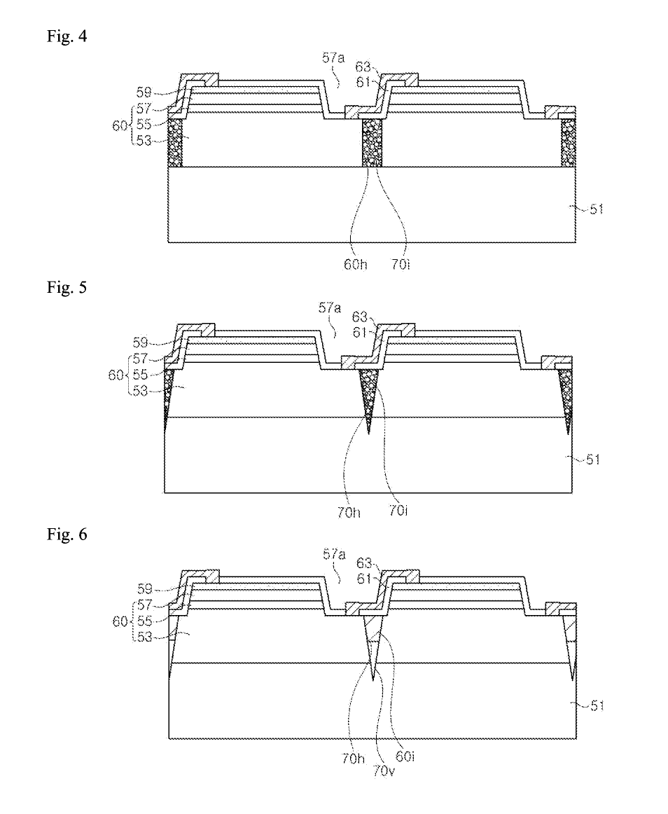

FIG. 2 is a sectional view of a light emitting diode according to one embodiment of the disclosed technology.

Referring to FIG. 2, the light emitting diode includes a substrate 51, a plurality of light emitting elements 60, an isolation trench 60h, an insulation material 60i, a transparent electrode 59, an insulation layer 61, and a wiring 63. The light emitting elements 60 include a first conductivity-type semiconductor layer 53, an active layer 55, and a second conductivity-type semiconductor layer 57.

The substrate 51 can be or include a growth substrate on which a gallium nitride-based semiconductor layer can be grown, for example, a sapphire substrate, a SiC substrate, a spinel substrate, or the like. The first conductivity-type semiconductor layer 53, the active layer 55 and the second conductivity-type semiconductor layer 57 can be grown on the substrate 51 by a growth technique such as MOCVD. Here, the first conductivity-type semiconductor layer 53 is relatively thicker than the second conductivity-type semiconductor layer 57. For example, the first conductivity-type semiconductor layer 53 has a thickness of about 3 μm or more, and the second conductivity-type semiconductor layer 57 has a thickness of less than about 1 μm. In some implementations, the first conductivity-type semiconductor layer 53 is an n-type semiconductor layer and the second conductivity-type semiconductor layer 57 is a p-type semiconductor layer.

The plural light emitting elements 60 are formed by patterning the first conductivity-type semiconductor layer 53, the active layer 55, and the second conductivity-type semiconductor layer 57. The light emitting elements 60 are electrically isolated from each other by the isolation trench 60h, and the first conductivity-type semiconductor layer 53 of each of the light emitting elements 60 has an upper surface exposed by the etched recess 57a. In some implementations, the etched recess 57a can be continuously formed around the light emitting elements 60. In some implementations, the etched recess 57a can be formed in some areas on which the wiring 63 is formed. The isolation trench 60h is formed around the light emitting elements 60, and at least a portion of the isolation trench 60h is formed in the etched recess 57a. As shown in FIG. 2, the etched recess 57a has a sidewall formed to have a gentler slope than a sidewall of the isolation trench 60h. The sidewall of the isolation trench 60h can have a relatively steep slope and an entrance of the isolation trench 60h can have a width of less than 5 μm. Here, the isolation trench 60h is formed using dry or wet etching.

The transparent electrode 59 is disposed on the second conductivity-type semiconductor layer 57 of each of the light emitting elements 60 and forms ohmic contact with the second conductivity-type semiconductor layer 57. The transparent electrode 59 can be formed to include a transparent oxide such as ITO or a transparent metal layer such as Ni/Au.

The insulation material 60i fills the isolation trench 60h or is included in the isolation trench 60h. The insulation material 60i can include a polyimide. The polyimide exhibits small thermal shrinkage due to excellent heat resistance thereof, and exhibits outstanding impact resistance, dimensional stability and insulation properties. In addition, the polyimide has a lower index of refraction (about 1.7) than that of gallium nitride (about 2.45) and thus is suitable for total reflection of light travelling in the first conductivity-type semiconductor layer 53.

The insulation material 60i is disposed in the isolation trench 60h and can have an upper surface which is flush with or disposed below the exposed upper surface of the first conductivity-type semiconductor layer 53.

The insulation layer 61 covers side surfaces of the light emitting elements 60, and has an opening exposing the upper surface of the first conductivity-type semiconductor layer 53 and an upper surface of the transparent electrode 59. The insulation layer 61 can be formed of or include silicon oxide or silicon nitride, and a portion of the insulation layer 61 can cover the upper surface of the insulation material 60i.

The wiring 63 electrically connects the first conductivity-type semiconductor layer 53 of one (first) light emitting element to the second conductivity-type semiconductor layer 57 of another (second) light emitting element. As shown in FIG. 2, the wiring 63 can connect the exposed upper surface of the first conductivity-type semiconductor layer 53 to the transparent electrode 59.

The wiring 63 is disposed on an upper side of the insulation material 60i and is insulated from the side surface of the second light emitting element 60 by the insulation layer 61. In addition, the side surface of the light emitting element 60, which is covered with the wiring 63, has a relatively gentle slope. Further, a portion of the side surface of the light emitting element 60, on which the wiring 63 is formed, has a smaller height than a total height of the light emitting element 60 or a height of the isolation trench 60h. Thus, since the wiring 63 can have a shorter length than a wiring of typical light emitting diodes, light absorption by the wiring 63 can be reduced, and the wiring 63 can be more easily formed and be prevented from suffering from disconnection.

According to this embodiment, since there is no need to form the wiring 63 in the isolation trench 60h, the isolation trench 60h can have a smaller width. Thus, reduction in light emitting area due to formation of the isolation trench 60h can be mitigated.

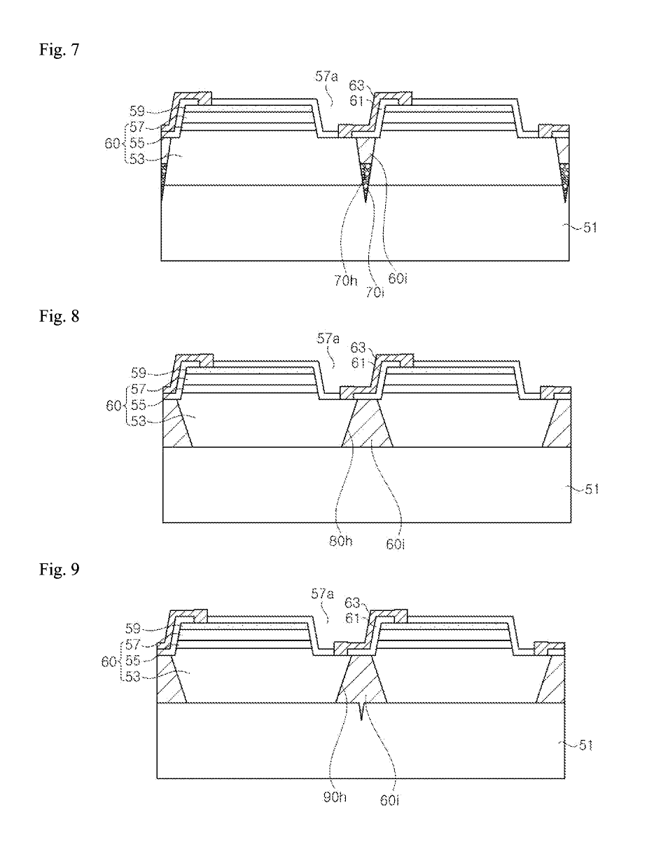

FIG. 3 is a sectional view of a light emitting diode according to another embodiment of the disclosed technology.

Referring to FIG. 3, the light emitting diode according to this embodiment is generally similar to the light emitting diode of FIG. 2 except that an isolation trench 70h is formed by laser machining.

The isolation trench 70h is formed by laser irradiation and thus can be extended to the interior of the substrate 51. Since the isolation trench 70h is formed by laser irradiation, the isolation trench 70h can have a smaller width with decreasing distance between the isolation trench 70h and the substrate 51. When the isolation trench 70h is formed by laser irradiation, phosphoric acid treatment (at 90° C. to 120° C. and for 5 minutes to 12 minutes) is performed to remove defects of a gallium nitride layer due to laser irradiation.

According to this embodiment, the isolation trench 70h is formed by laser machining and thus can have a further reduced width.

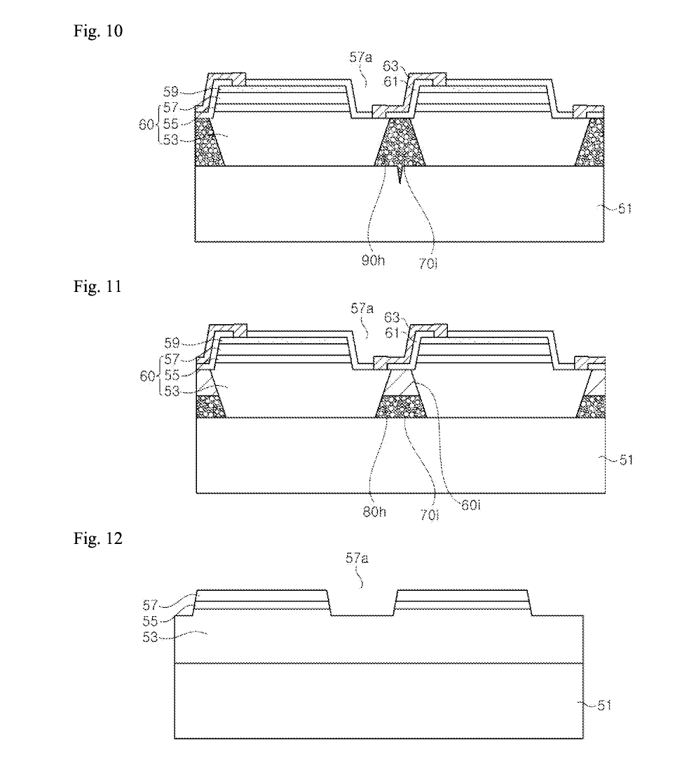

FIG. 4 is a sectional view of a light emitting diode according to a further embodiment of the disclosed technology.

Referring to FIG. 4, the light emitting diode according to this embodiment is generally similar to the light emitting diode of FIG. 2 except that an insulation material 70i is formed of or includes nanoparticles.

That is, according to this embodiment, the insulation material 70i includes nanoparticles, and the nanoparticles can be or include, for example, nano-scale spherical silica. Nanoparticles having a relatively low index of refraction, for example, an index of refraction of about 1.46, is used, thereby improving light extraction efficiency through reflection of light travelling in the first conductivity-type semiconductor layer 53 by the nanoparticles. Further, since air having an index of refraction of 1 remains between the nanoparticles, light can be reflected better.

FIG. 5 is a sectional view of a light emitting diode according to yet another embodiment of the disclosed technology.

Referring to FIG. 5, the light emitting diode according to this embodiment is generally similar to the light emitting diode of FIG. 3 except that the insulation material 70i is formed of or includes nanoparticles, as described with reference to FIG. 4.

FIG. 6 is a sectional view of a light emitting diode according to yet another embodiment of the disclosed technology.

Referring to FIG. 6, the light emitting diode according to this embodiment is generally similar to the light emitting diode of FIG. 3 except that an air gap 70v remains between the insulation material 60i and the substrate 51. That is, the insulation material 60i does not completely fill the isolation trench 70h and the air gap 70v is formed in a lower portion of the isolation trench 70h.

Since the air gap 70v has a reflectivity of 1 and thus is more advantageous for total internal reflection than the polyimide 60i, the light emitting diode can have further improved light extraction efficiency.

FIG. 7 is a sectional view of a light emitting diode according to yet another embodiment of the disclosed technology.

Referring to FIG. 7, the light emitting diode according to this embodiment is generally similar to the light emitting diode of FIG. 6 except that nanoparticles 70i instead of the air gap 70v are disposed.

The nanoparticles 70i are disposed in a lower portion of the isolation trench 70h, and the polyimide 60i can be disposed on the nanoparticles 70i.

FIG. 8 is a sectional view of a light emitting diode according to yet another embodiment of the disclosed technology.

Referring to FIG. 8, the light emitting diode according to this embodiment is generally similar to the light emitting diode of FIG. 2 except that an isolation trench 80h has a reversely inclined sidewall.

Since light travelling in the first conductivity-type semiconductor layer 53 can be easily emitted to outside by adjusting a slope of the sidewall, the light emitting diode can have further improved light extraction efficiency.

The isolation trench 80h can be formed by forming the isolation trench 60h in FIG. 2, followed by sulfuric-phosphoric acid treatment (H₂SO₄:H₃PO₄=3:1, 280° C., about 5 minutes).

FIG. 9 is a sectional view of a light emitting diode according to yet another embodiment of the disclosed technology.

Referring to FIG. 9, the light emitting diode according to this embodiment is generally similar to the light emitting diode of FIG. 3 except that an isolation trench 90h has a reversely inclined sidewall.

The isolation trench 90h can be formed by forming the isolation trench 70h in FIG. 3, followed by sulfuric-phosphoric acid treatment (H₂SO₄:H₃PO₄=3:1, 280° C., about 5 minutes). Thus, the isolation trench 70h that is extended to an interior of the substrate 51 remains.

FIG. 10 is a sectional view of a light emitting diode according to yet another embodiment of the disclosed technology.

Referring to FIG. 10, the light emitting diode according to this embodiment is generally similar to the light emitting diode of FIG. 8 except that an insulation material 70i is formed of or includes nanoparticles, as described with reference to FIG. 4.

FIG. 11 is a sectional view of a light emitting diode according to yet another embodiment of the disclosed technology.

Referring to FIG. 11, the light emitting diode according to this embodiment is generally similar to the light emitting diode of FIG. 10 except that nanoparticles 70i are disposed in a lower portion of the isolation trench 90h and a polyimide 60i is disposed in an upper portion of the isolation trench 90h.

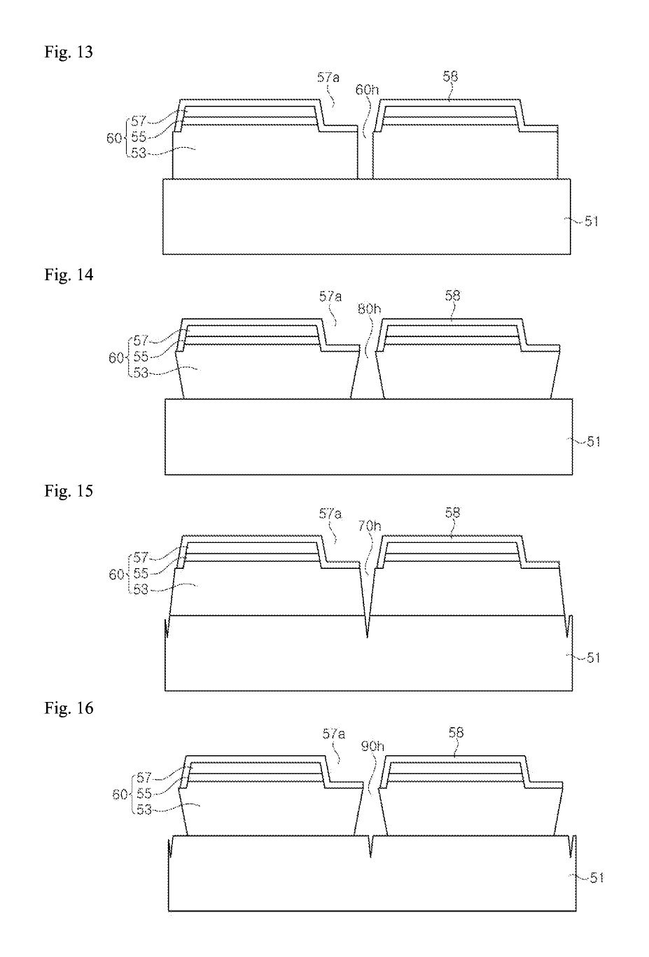

FIGS. 12 and 13 are sectional views for explaining a method for manufacturing a light emitting diode according to one embodiment of the disclosed technology.

Referring to FIG. 12, a first conductivity-type semiconductor layer 53, an active layer 55 and a second conductivity-type semiconductor layer 57 are grown on a substrate 51. The semiconductor layers are formed of or includes a gallium nitride-based semiconductor and can be grown using a growth technique such as MOCVD or MBE and the like. Although not shown in FIG. 12, a buffer layer can be grown before growth of the first conductivity-type semiconductor layer 53.

Next, an etched recess 57a exposing the first conductivity-type semiconductor layer 53 is formed by etching the second conductivity-type semiconductor layer 57 and the active layer 55. The first conductivity-type semiconductor layer 53 has an upper surface exposed by the etched recess 57a. The etched recess 57a has a sidewall having a relatively gentle slope, as shown in FIG. 12.

Referring to FIG. 13, an isolation trench 60h electrically isolating a plurality of light emitting elements 60 from one another is formed. Before the isolation trench 60h is formed, a mask pattern 58 covering other regions excluding the isolation trench 60h can be formed. The mask pattern 58 can be formed of or include silicon oxide or silicon nitride.

Next, the isolation trench 60h can be formed by dry or wet etching of the region exposed by the mask pattern 58.

The mask pattern 58 can be removed after formation of the isolation trench 60h. Next, an insulation material 60i (see FIG. 2) can be formed to fill the isolation trench 60h, followed by formation of a transparent electrode 59, an insulation layer 61 and a wiring 63, thereby manufacturing the light emitting diode as shown in in FIG. 2. The insulation material 60i can be formed by spin coating of a photosensitive polyimide, followed by exposure to light and development to remove the polyimide in the remaining regions excluding the polyimide in the isolation trench 60h.

The transparent electrode 59 can be formed before formation of the isolation trench 60h, the mask pattern 58 or the insulation material 60i.

The light emitting diode as shown in FIG. 4 can be manufactured by filling the isolation trench 60h with nanoparticles, for example, an insulation material 70i (see FIG. 4), instead of the insulation material 60i. The insulation material 70i can be formed by dispersing the nanoparticles in water or another solvent, followed by spin coating.

FIG. 14 is a sectional view of a method for manufacturing a light emitting diode according to another embodiment of the disclosed technology.

Referring to FIG. 14, before removal of the mask pattern 58 and after formation of the isolation trench 60h as described above with reference to FIGS. 12 and 13, sulfuric-phosphoric acid treatment (H₂SO₄:H₃PO₄=3:1, 280° C., about 5 minutes) can be performed, thereby forming an isolation trench 80h having a reversely inclined sidewall.

Next, the mask pattern 58 can be removed, followed by formation of an insulation material 60i (see FIG. 8), a transparent electrode 59, an insulation layer 61 and a wiring 63, thereby manufacturing the light emitting diode as shown in FIG. 8.

FIG. 15 is a sectional view of a method for manufacturing a light emitting diode according to a further embodiment of the disclosed technology.

Referring to FIG. 15, the method for manufacturing a light emitting diode according to this embodiment is generally similar to the method for manufacturing a light emitting diode described with reference to FIGS. 12 and 13 except that an isolation trench 70h is formed by laser machining.

The isolation trench 70h isolating the light emitting elements 60 from one another can be formed by laser irradiation and phosphoric acid treatment can be performed to remove gallium nitride damaged by laser irradiation. The isolation trench 70h can be formed to be extended to the interior of the substrate 51 by laser machining.

According to this embodiment, a mask pattern 58 can be formed before laser irradiation so as to define an entrance of the isolation trench 70h. However, other implementations are also possible without being limited thereto. For example, since a mask material can be removed by laser irradiation, the semiconductor layers in which the isolation trench 70h is formed are covered with a mask material layer, followed by direct laser irradiation, thereby forming the isolation trench 70h.

The light emitting diode as shown in FIG. 3 may be manufactured in the following manners. After the isolation trench 70h is formed, the mask pattern 58 is removed, an insulation material 60i (see FIG. 3) for filling the isolation trench 70h is formed, and a transparent electrode 59, an insulation layer 61 and a wiring 63 are formed. The insulation material 60i can be formed such that an air gap 70v (see FIG. 6) remains, thereby manufacturing the light emitting diode as shown in FIG. 6. In addition, nanoparticles 70i (see FIG. 5) can fill the isolation trench 70h instead of the insulation material 60i, thereby manufacturing the light emitting diode as shown in FIG. 5. Further, the nanoparticles and the polyimide can also be combined, thereby manufacturing the light emitting diode as shown in FIG. 7.

FIG. 16 is a sectional view for explaining a method for manufacturing a light emitting diode according to yet another embodiment of the disclosed technology.

Referring to FIG. 16, the method for manufacturing a light emitting diode according to this embodiment further includes forming an isolation trench 90h having a reversely inclined sidewall by sulfuric-phosphoric acid treatment (H₂SO₄:H₃PO₄=3:1, 280° C., about 5 minutes) before removal of the mask pattern 58 and after formation of the isolation trench 70h as described above in FIG. 15.

Next, the mask pattern 58 is removed, followed by filling the isolation trench 90h with the insulation material 60i, the insulation material 70i, or a combination thereof, thereby manufacturing the light emitting diode as shown in FIG. 9, 10 or 11.

What is claimed is:

1. A light emitting diode comprising:
a substrate;
a plurality of light emitting elements arranged on the substrate;
an isolation trench isolating adjacent light emitting elements from each other;
an insulation material filling at least a portion of the isolation trench;
a wiring electrically connecting two adjacent light emitting elements to each other; and
an insulation layer insulating the wiring from a side surface of the light emitting elements,
wherein each of the light emitting elements includes a first conductivity-type semiconductor layer, an active layer and a second conductivity-type semiconductor layer,
the first conductivity-type semiconductor layer has an upper surface exposed by removing the second conductivity-type semiconductor layer and the active layer, the exposed upper surface adjoining the isolation trench,
the wiring is disposed over an upper side of the insulation material, and
the insulation material has an upper surface which is flush with or disposed below the exposed upper surface of the first conductivity-type semiconductor layer.

2. The light emitting diode of claim 1, wherein the wiring electrically connects the upper surface of the first conductivity-type semiconductor layer of a first light emitting element to the second conductivity-type semiconductor layer of a second light emitting element.

3. The light emitting diode of claim 2, wherein a portion of a side surface of the second light emitting element is covered with the wiring and has a gentler slope than a sidewall of the isolation trench.

4. The light emitting diode of claim 1, wherein the isolation trench extends to an interior of the substrate.

5. The light emitting diode of claim 4, wherein the isolation trench is formed by laser machining to have a decreasing width toward the substrate.

6. The light emitting diode of claim 1, wherein the insulation material includes a polyimide.

7. The light emitting diode of claim 1, wherein the insulation material includes nano-scale silica.

8. The light emitting diode of claim 1, wherein the insulation material includes nano-scale silica and a polyimide disposed over the silica.

9. The light emitting diode of claim 1, wherein a sidewall of the isolation trench has a reverse slope.

10. The light emitting diode of claim 1, wherein the isolation trench has an entrance having a width of 5 μm or less.

11. The light emitting diode of claim 1, wherein a portion of the insulation layer covers an upper surface of the insulation material.

12. A light emitting diode comprising:
a substrate;
a plurality of light emitting elements arranged on the substrate;
an isolation trench isolating adjacent light emitting elements from each other;
an insulation material filling at least a portion of the isolation trench;
a wiring electrically connecting two adjacent light emitting elements to each other; and
an insulation layer insulating the wiring from a side surface of the light emitting elements,
wherein each of the light emitting elements includes a first conductivity-type semiconductor layer, an active layer and a second conductivity-type semiconductor layer,
the first conductivity-type semiconductor layer has an upper surface exposed by removing the second conductivity-type semiconductor layer and the active layer, the exposed upper surface adjoining the isolation trench,
the wiring is disposed over an upper side of the insulation material, and
an air gap is disposed between the insulation material and the substrate.

13. The light emitting diode of claim 12, wherein the insulation material includes nano-scale silica and a polyimide disposed over the silica.

14. The light emitting diode of claim 12, wherein a portion of the insulation layer covers an upper surface of the insulation material.

15. A method for manufacturing a light emitting diode, comprising:
growing a first conductivity-type semiconductor layer, an active layer and a second conductivity-type semiconductor layer on a substrate;
forming an etched recess exposing the first conductivity-type semiconductor layer by etching the second conductivity-type semiconductor layer and the active layer;
forming an isolation trench to electrically isolate a plurality of light emitting elements from one another, at least a portion of the isolation trench being formed in the etched recess;
filling at least a portion of the isolation trench with an insulation material;
forming an insulation layer covering a side surface of the plural light emitting elements; and
forming a wiring electrically connecting adjacent light emitting elements,
wherein a portion of the insulation layer covers the upper surface of the insulation material.

16. The method of claim 15, wherein the insulation material has an upper surface which is flush with or disposed below the bottom surface of the etched recess.

17. The method of claim 15, wherein a sidewall of the etched recess has a gentler slope than a sidewall of the isolation trench.

18. The method of claim 15, wherein the forming the isolation trench includes removing the first conductivity-type semiconductor layer by etching or laser machining.

19. The method of claim 18, wherein the forming the isolation trench further includes performing sulfuric-phosphoric acid treatment after the first conductivity-type semiconductor layer is removed by etching or laser machining.

20. The method of claim 15, wherein the insulation material includes a polyimide or nano-scale silica.
